(19) United States
(12) Patent Application Publication
(10) Pub. No.: US 2015/0170970 A1
(43) Pub. Date: Jun. 18, 2015

(54) STRAIN CONTROL FOR ACCELERATION OF EPITAXIAL LIFT-OFF

(71) Applicant: The Regents of the University of Michigan, Ann Arbor, MI (US)

(72) Inventors: Stephen R. Forrest, Ann Arbor, MI (US); Kyusang Lee, Ann Arbor, MI (US); Jeramy Zimmerman, Golden, CO (US)

(21) Appl. No.: 14/405,534

(22) PCT Filed: Jun. 4, 2013
(86) PCT No.: PCT/US2013/044028

§ 371 Date: Dec. 4, 2014

Related U.S. Application Data
(60) Provisional application No. 61/655,084, filed on Jun. 4, 2012.

(51) Int. Cl. H01L 21/78; H01L 31/18

(52) U.S. Cl. CPC H01L 21/7813; H01L 31/1892

(57) ABSTRACT

There is disclosed a thin film device for epitaxial lift off comprising a handle and one or more straining layers disposed on the handle, wherein the one or more straining layers induce a curvature of the handle. There is also disclosed a method of fabricating a thin film device for epitaxial lift off comprising, depositing one or more straining layers on a handle, wherein the one or more straining layers induce at least one strain on the handle chosen from tensile strain, compressive strain and near-neutral strain. There is also disclosed a method for epitaxial lift off comprising, depositing an epilayer over a sacrificial layer disposed on a growth substrate; depositing one or more straining layers on at least one of the growth substrate and a handle; bonding the handle to the growth substrate; and etching the sacrificial layer.

### CROSS-REFERENCE TO RELATED APPLICATION

This application claims the benefit of priority to U.S. Provisional Patent Application No. 61/655,084, filed on Jun. 4, 2012, which is incorporated by reference herein in its entirety.

### STATEMENT REGARDING FEDERALLY SPONSORED RESEARCH

This invention was made with Government support under W911nF-08-2-0004 awarded by the Army Research Office. The government has certain rights in the invention.

### JOINT RESEARCH AGREEMENT

The subject matter of this application was made by, on behalf of, and/or in connection with one or more of the following parties to a joint university-corporation research agreement: University of Michigan and Global Photonic Energy Corporation. The agreement was in effect on and before the date the subject matter of this application was made, and such was made as a result of activities undertaken within the scope of the agreement.

The disclosure generally relates to methods of making, electrically active, optically active, solar, semiconductor and thin-film materials, such as photovoltaic (PV) devices through the use of epitaxial lift off (ELO).

Photosensitive optoelectronic devices convert electromagnetic radiation into electricity. Solar cells, also called PV devices, are a type of photosensitive optoelectronic device that is specifically used to generate electrical power. PV devices, which may generate electrical energy from light sources other than sunlight, can be used to drive power consuming loads to provide, for example, lighting, heating, or to power electronic circuitry or devices such as calculators, radios, computers or remote monitoring or communications equipment.

To produce internally generated electric fields, the usual method is to juxtapose two layers of material with appropriately selected conductive properties, especially with respect to their distribution of molecular quantum energy states. The interface of these two materials is called a photovoltaic junction. In traditional semiconductor theory, materials for forming PV junctions have been denoted as generally being of either n or p type. Here n-type denotes that the majority carrier type is the electron. This could be viewed as the material having many electrons in relatively free energy states. The p-type denotes that the majority carrier type is the hole. Such material has many holes in relatively free energy states. The type of the background, i.e., not photo-generated, majority carrier concentration depends primarily on unintentional doping by defects or impurities. The type and concentration of impurities determine the value of the Fermi energy, or level, within the gap between the conduction band minimum and valance band maximum energies. The Fermi energy characterizes the statistical occupation of molecular quantum energy states denoted by the value of energy for which the probability of occupation is equal to ½. A Fermi energy near the conduction band minimum energy indicates that electrons are the predominant carrier. A Fermi energy near the valence band maximum energy indicates that holes are the predominant carrier. Accordingly, the Fermi energy is a primary characterizing property of traditional semiconductors and the prototypical PV junction has traditionally been the p-n interface.

Conventional inorganic semiconductor PV cells employ a p-n junction to establish an internal field. High-efficiency PV devices are typically produced on expensive, single crystal growth substrates. These growth substrates may include single crystal wafers, which can be used for creating a perfect lattice and structural support for the epitaxial growth of active layers, also known as “epilayers.” These epilayers may be integrated into PV devices with their original growth substrates intact. Alternatively, those epilayers may be removed and recombined with a host substrate.

In some instances, it may be desirable to transfer the epilayers to host substrates that exhibit desirable optical, mechanical, or thermal properties. For example, Gallium Arsenide (GaAs) epilayers may be grown on Silicon (Si) substrates. However, the electronic quality of the resulting material may be insufficient for certain electronic applications. Therefore, it may be desirable to preserve the high material quality of the lattice-matched epilayers, while allowing the integration of those epilayers into other substrates. This may be accomplished by a method known as epitaxial liftoff. In epitaxial liftoff processes, epilayers may be “lifted off” growth layers and recombined (e.g., bonded or adhered) to a new host substrate.

Although they may provide desirable epitaxial growth characteristics, typical growth substrates can be thick and create excess weight, and the resulting devices tend to be fragile and require bulky support systems. Epitaxial liftoff may be a desirable way to transfer epilayers from their growth substrates to more efficient, light-weight, and flexible host substrates. Given the relative scarcity of typical growth substrates and the desirable characteristics that they impart on resulting cell structures, it may be desirable to recycle and/or reuse growth substrates in subsequent epitaxial growths.

The ELO process is attractive for solar cell applications and provides for a potential reduction of production cost for III-V based device by reusing the parent wafers. For the optoelectronic devices, such as photovoltaic cells and photodetectors, it requires approximately half of the active-region thickness to absorb an equivalent amount of incident radiation compared to conventional substrate wafer-based devices by fabricating the thin film devices with back side reflector. Thinner active layer also enables production cost reduction by reducing materials consumption and growth time for the epitaxial layers. Furthermore, the back-side reflector prevents parasitic absorption of photons emitted via luminescence into the substrate and allows for increased “photon recycling,” a necessary requirement for achieving the Shockley-Queisser Limit. This photon recycling allows for increased open circuit voltage in lifted off cells as compared to substrate cells.

To accelerate the lateral etching process of the sacrificial layer, a curvature to a lifted off thin film and flexible handle material (e.g. plastic, wax, metal foil, photoresist, etc) is generally applied. This is done by bending away from the wafer using weight or curving the handle to open a gap between the wafer and the epi-layer. However, this process requires a precise epi-layer support set-up or an additional transfer step. Further, if the epi-layer support setup induces too much strain on the epilayer or too much film curvature, cracks in the thin single crystal film can result.

There remains a need to expedite the ELO process by controlling the strain on the handle and simplifying the lift-off set-up.

One embodiment of the present disclosure is directed to a thin film device for epitaxial lift off comprising a handle and one or more straining layers disposed on the handle, wherein the one or more straining layers induce a curvature of the handle.

In another embodiment, the present disclosure is directed to a thin film device for epitaxial lift off comprising a growth substrate, a handle, and one or more straining layers disposed on at least one of the growth substrate and the handle, wherein the handle optionally having the one or more straining layers disposed thereon is bonded to the growth substrate, and wherein the one or more straining layers induce at least one strain on the handle chosen from tensile strain, compressive strain and near-neutral strain.

In another embodiment, the present disclosure is directed to a thin film device for epitaxial lift off comprising an epilayer disposed on a growth substrate, a handle, and one or more straining layers disposed on at least one of the growth substrate and the handle, wherein the handle optionally having the one or more straining layers disposed thereon is bonded to the growth substrate, and wherein the one or more straining layers induce at least one strain on at least one of the handle and epilayer chosen from tensile strain, compressive strain, and near-neutral strain. In some embodiments, the one or more straining layers induce at least one strain on the handle and the epilayer.

In another embodiment, the present disclosure is directed to a thin film device for epitaxial lift off comprising a sacrificial layer and an epilayer disposed on a growth substrate, a handle, and one or more straining layers disposed on at least one of the growth substrate and the handle, wherein the handle optionally having the one or more straining layers disposed thereon is bonded to the growth substrate, and wherein the one or more straining layers induce at least one strain on at least one of the sacrificial layer, the epilayer and the handle chosen from tensile strain, compressive strain, and near-neutral strain. In some embodiments, the one or more straining layers induce at least one strain on the sacrificial layer, the epilayer, and the handle.

In another embodiment, the present disclosure provides a thin film device for epitaxial lift off comprising at least one sacrificial layer, and at least one straining layer disposed on a handle, wherein the straining layer is composed of at least one material chosen from a metal, a semiconductor, a dielectric and a non-metal, and wherein the straining layer induces a curvature of the handle.

In yet another embodiment, the present disclosure provides a thin film device for epitaxial lift off comprising at least one sacrificial layer, and at least one straining layer disposed on a handle, wherein the straining layer is composed of at least one material chosen from a metal, a semiconductor, a dielectric and a non-metal, and wherein the handle is amenable to curvature under tensile or compressive strain from the straining layer.

In another embodiment, the present disclosure provides for a straining layer composed of a metal. Suitable examples of this metal include pure metals such as Gold, Nickel, Silver, Copper, Tungsten, Platinum, Palladium, Tantalum, Molybdenum, or Chromium, or metal alloys containing Iridium, Gold, Silver, Copper, Tungsten, Platinum, Palladium, Tantalum, Molybdenum, and/or Chromium.

In some embodiments of the present disclosure, the straining layer induces curvature of a handle. In some embodiments, the one or more straining layers induce curvature of the handle upon etching the sacrificial layer. In some embodiments, the one or more straining layers induce curvature of the handle upon parting with the growth substrate. In some embodiments, the curvature of the handle is toward a growth substrate. In some embodiments, the straining layer induces a curvature of the handle away from a growth substrate. In some embodiments, the straining layer minimizes curvature of the handle.

In one embodiment, the present disclosure provides for a method of fabricating a thin film device for epitaxial lift off comprising, depositing one or more straining layers on a handle, wherein the one or more straining layers induce at least one strain on the handle chosen from tensile strain, compressive strain and near-neutral strain. In some embodiments, the method can induce a curvature of the handle.

In another embodiment, the present disclosure provides a straining layer which induces tensile strain to induce a curvature of the handle towards a growth substrate.

In one embodiment, the present disclosure provides a method of fabricating a thin film device for epitaxial lift off comprising, providing a growth substrate and a handle, depositing one or more straining layers on at least one of the growth substrate and the handle, and bonding the handle optionally having the one or more straining layers disposed thereon to the growth substrate.

In yet another embodiment, the present disclosure provides a method for epitaxial lift off comprising, depositing an epilayer over a sacrificial layer disposed on a growth substrate; depositing one or more straining layers on at least one of the growth substrate and a handle; bonding the handle to the growth substrate; and etching the sacrificial layer.

A further embodiment of the present disclosure is directed to a thin film solar cell device comprising at least one layer disposed on a growth substrate that is bonded to a handle, wherein the handle is both sufficiently flexible and has a curvature that expedites epitaxial lift off. Another embodiment of the present disclosure is directed to a thin film solar cell device comprising at least one layer disposed on a growth substrate that is bonded to a handle, wherein a difference in coefficient of thermal expansion between the wafer and handle is used to create a curvature in the handle to expedite epitaxial lift off.

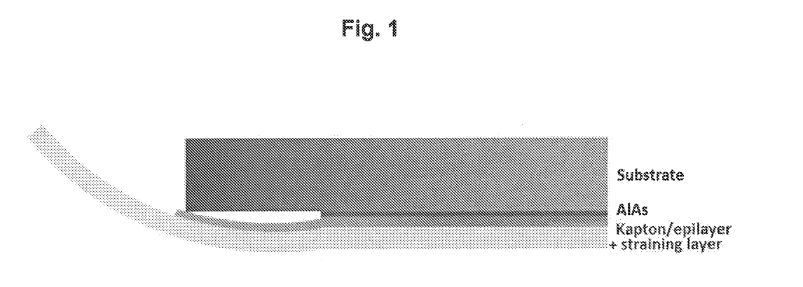

FIG. 1 depicts an exemplary embodiment of a thin film device for epitaxial lift off comprising a growth substrate and a handle, e.g., a Kapton sheet, wherein a straining layer induces a curvature of the handle.

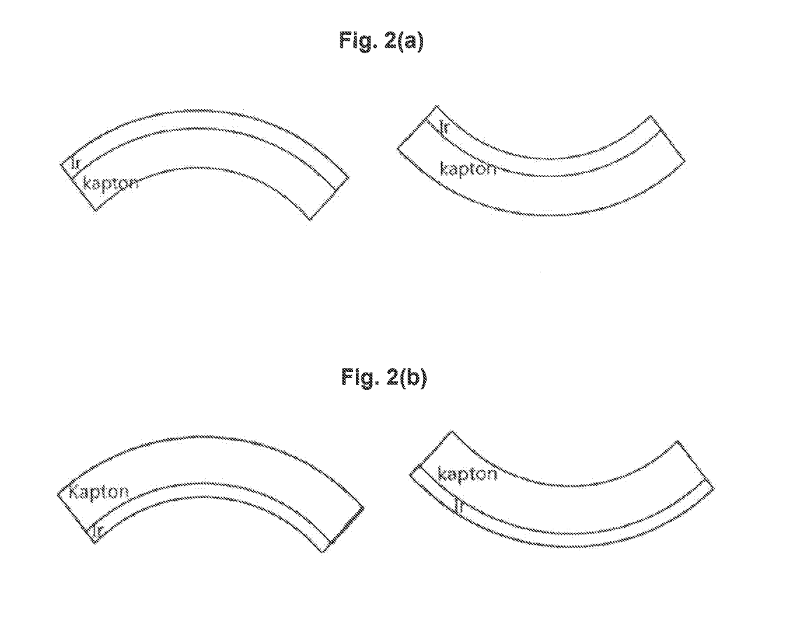

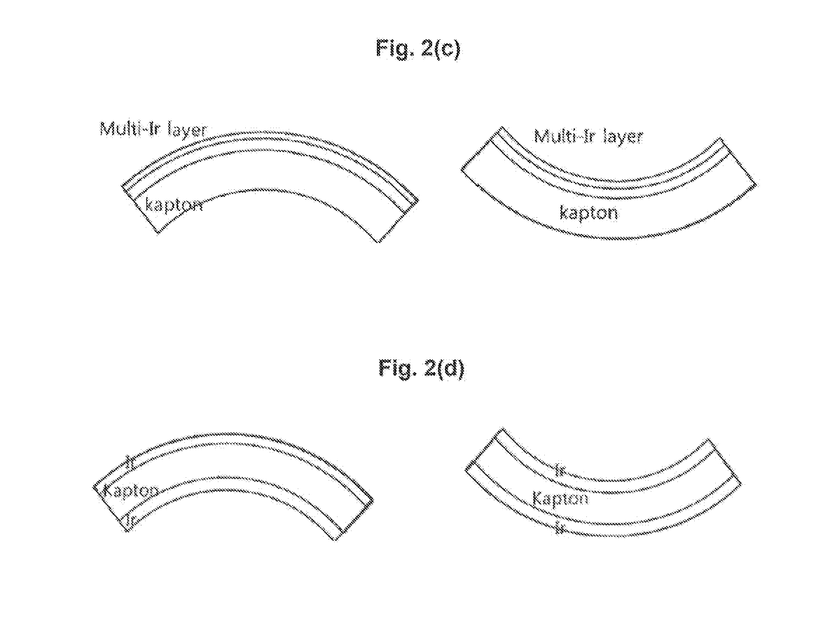

FIG. 2 depicts various combinations of sputtered Ir with tensile and compressive strain having a single stressor layer on top of handle (a), on bottom of handle (b), or multiple layers on top of handle with varying strains (c), or layers with variable strains on both sides of the handle (d).

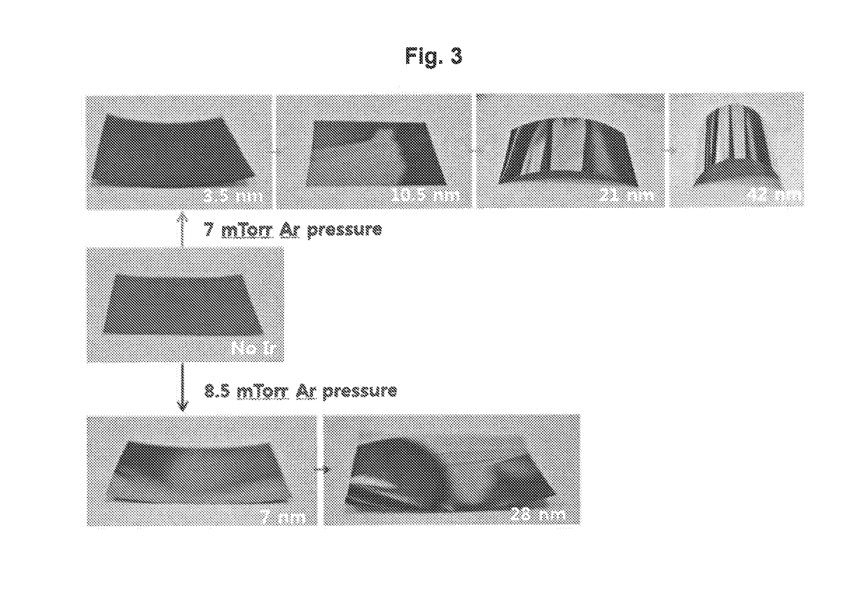

FIG. 3 depicts a 50 μm Kapton sheet with 3.5 nm, 10.5 nm, 21 nm and 42 nm thick sputtered Ir under 7 mTorr sputtering chamber pressure and with 7 nm and 28 nm sputtered Ir under 8.5 mTorr sputtering chamber pressure and a control sheet without Ir.

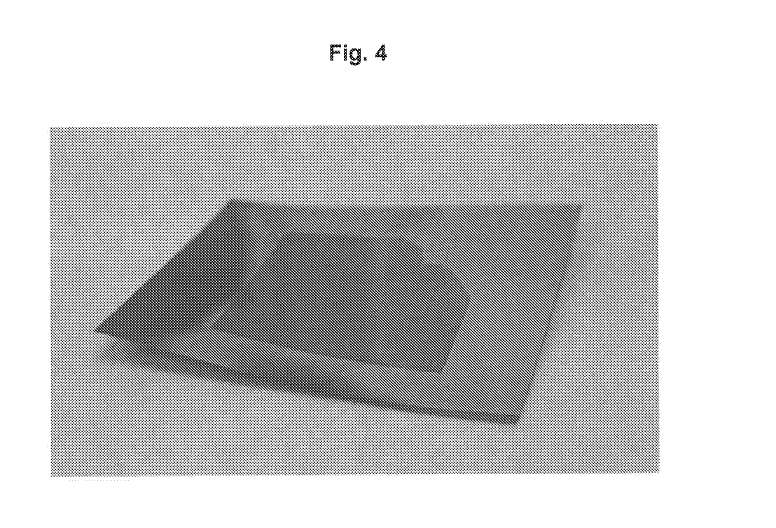

FIG. 4 depicts a picture of a cold-weld bonded and lifted off thin film on a strained handle.

As used herein, the term “layer” refers to a member or component of a photosensitive device whose primary dimension is X-Y, i.e., along its length and width, and is typically perpendicular to the plane of incidence of the illumination. It should be understood that the term “layer” is not necessarily limited to single layers or sheets of materials. A layer can comprise laminates or combinations of several sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) or material(s).

As used herein, the term “III-V material” may be used to refer to compound crystals containing elements from group IIIA and group VA of the periodic table. More specifically, the term III-V material may be used herein to refer to compounds which are combinations of the group of Gallium (Ga), Indium (In) and Aluminum (Al), and the group of Arsenic (As), Phosphorous (P), Nitrogen (N), and Antimony (Sb). Representative materials may include GaAs, InP, InGaAs, AlAs, AlGaAs, InGaAsP, InGaAsPN, GaN, InGaN, InGaP, GaSb, GaAlSb, InGaTeP, and InSb and all related compounds. The term “Group IV” comprises such semiconductors as Si and Ge in column IVA of the periodic chart. Group II-VI comprises such semiconductors as CdS and CdTe, for example, that reside in Groups IIA and VIA of the periodic chart.

As used herein, the expression “disposed on” permits other materials or layers to exist between a material being disposed and the material on which it is disposed. Likewise, the expression “bonded to” permits other materials or layers to exist between a material being bonded and the material to which it is bonded.

As used herein, a straining layer that induces a curvature of a handle toward a growth substrate means that the straining layer induces the handle to take a concave shape from the point of reference of the growth substrate.

As used herein, a straining layer that induces a curvature of a handle away from a growth substrate means that the straining layer induces the handle to take a convex shape from the point of reference of the growth substrate.

The term “strain” as used herein can be defined in terms of the residual strain in the deposited layer. The strain can be tensile, compressive or near-neutral. A tensile strain will curve the handle towards the straining layer, a compressive strain will curve the handle away from the straining layer, and a near-neutral strain will not cause any significant curvature to the handle. In one embodiment, the strain applied to a handle material is tensile which accelerates curvature of the handle towards a wafer.

The thin film devices described herein may be photosensitive devices. In some embodiments, the thin film devices described herein are solar cell devices.

The present disclosure also relates to employing a protection layer disposed between a growth substrate and at least one epitaxial layer. U.S. Pat. No. 8,378,385 and U.S. Patent Publication No. 2013/0043214 are hereby incorporated by reference for their disclosure of growth structures and materials, for example, a growth structure comprising a growth substrate, protection layers, a sacrificial layer, and an epilayer.

The present disclosure further relates to removal of the protection layer and contaminants from the ELO process by a pre-cleaning process that at least partially decomposes the protection layer surface with rapid thermal annealing (RTA). In another embodiment, the combination of epitaxial protection layers and rapid thermal decomposition provides nearly identical surface quality with the fresh wafer.

In some embodiments of the present disclosure, a thin film device for epitaxial lift off comprises a handle and one or more straining layers disposed on the handle, wherein the one or more straining layers induce a curvature of the handle. For example, FIGS. 2(a) and 2(b) depict a straining layer, e.g., an Ir layer, disposed on a handle, e.g., a Kapton sheet, wherein the Ir layer induces curvature of the handle through tensile or compressive strain.

In some embodiments of the present disclosure, a thin film device comprises a growth substrate, a handle, and one or more straining layers disposed on at least one of the growth substrate and the handle, wherein the handle optionally having the one or more straining layers disposed thereon is bonded to the growth substrate, and wherein the one or more straining layers induce at least one strain on the handle chosen from tensile strain, compressive strain and near-neutral strain. In some embodiments, the at least one strain on the handle induces a curvature of the handle. In some embodiments, one or more straining layers are disposed on the growth substrate and the handle. FIG. 1 shows an exemplary embodiment of a thin film device for epitaxial lift off comprising a growth substrate and a handle, e.g., a Kapton sheet, wherein a straining layer induces a curvature of the handle.

In some embodiments, the thin film device further comprises an epilayer disposed on the growth substrate, wherein the one or more straining layers induce at least one strain on at least one of the handle and the epilayer chosen from tensile strain, compressive strain and near-neutral strain. In some embodiments, the one or more straining layers induce at least one strain on the handle and the epilayer.

In some embodiments, the thin film device further comprises a sacrificial layer and an epilayer disposed on the growth substrate, wherein the one or more straining layers induce at least one strain on at least one of the sacrificial layer, the epilayer, and the handle chosen from tensile strain, compressive strain and near-neutral strain. In some embodiments, the epilayer is disposed on the sacrificial layer. In some embodiments, the one or more straining layers induce at least one strain on the sacrificial layer, the epilayer and the handle.

In some embodiments, an epilayer is disposed on the growth substrate. In some embodiments, the epilayer comprises gallium arsenide (GaAs), dopants, or alloys and combinations thereof. In some embodiments, a sacrificial layer is disposed between the growth substrate and an epilayer. In one embodiment, the sacrificial layer comprises aluminum arsenide, alloys and combinations thereof. The sacrificial layer may have a thickness ranging from about 1 nm to about 200 nm, such as, for example, from about 2 nm to about 100 nm, from about 3 nm to about 50 nm, from about 5 nm to about 25 nm, and from about 8 nm to about 15 nm.

In yet other embodiments, the sacrificial layer may be exposed to a wet-etch solution during the etch process. The wet etch solution may contain hydrofluoric acid. The wet etch solution may also contain at least one surfactant, at least one buffer, or any combination thereof. In yet another embodiment, the sacrificial layer is a phosphide containing compound such as InGaP, InAlP, or InP. In some embodiments, the phosphide containing material is removed by etching in HCL-based etches.

In some embodiments, strain is applied to a handle material to facilitate lift off of thin films. In yet another embodiment, the applied strain curves the handle inward toward a growth substrate.

One or more straining layers, as described herein, may be disposed on a handle material in any orientation, i.e., back, front and sides of the handle. In some embodiments, the handle has a top surface and a bottom surface, the one or more straining layers being disposed on the top surface of the handle, the bottom surface of the handle, or both.

In one embodiment, the straining layer is composed of at least one material chosen from a metal, a semiconductor, a dielectric and a non-metal. In certain embodiments, the at least one material and can be present in thicknesses ranging from about 1 nm to about 10000 nm, based on the thickness of the thin film, such as, for example, from about 1 nm to about 500 nm, from about 2 nm to about 250 nm, from about 3 nm to about 100 nm, from about 4 nm to about 100 nm, and from about 5 nm to about 40 nm.

Suitable examples of the metals that can comprise the straining layers include metals chosen from Iridium, Gold, Nickel, Silver, Copper, Tungsten, Platinum, Palladium, Tantalum, Molybdenum, Chromium, and alloys thereof. In certain embodiments, the metals are chosen for their resistance to the ELO etchant of choice (e.g. HF acid). In a further embodiment, metals that are resistant to HF can be used to form a straining layer. In another embodiment, a non-HF resistant metal is used in combination with a barrier layer to induce curvature of the handle.

The straining layers can also be composed of a dielectric chosen from, for example, various nitrides, carbides, etc., a semiconductor chosen from, for example, group II-VI, III-V, and IV semiconductors, and/or a non-metal chosen from, for example, polymers, elastomers, and waxes. For instance, in some embodiments, at least one straining layer comprises at least one strained semiconductor epilayer. In some embodiments, at least one straining layer comprises at least one material chosen from InAs, GaAs, AlAs, InP, GaP, AlP, InSb, GaSb, AlSb, InN, GaN, and AlN.

In a further embodiment, Ir metal is sputtered on a handle to induce strain. Both tensile and compressive strains are applied to the handle by controlling the Ar sputtering gas pressure and the metal thickness. In yet another embodiment, and as shown in FIG. 3, a sputtering pressure of 7 mTorr is applied, as a means for providing tensile stress when the metal thickness is greater than 10 nm. In another embodiment, also shown in FIG. 3, a sputtering pressure of 8.5 mTorr is applied as a means for providing compressive stress to the handle. Also, the applied strain can be controlled by sputtering or evaporating or electroplating the straining layer on the back side of a handle, e.g., a flexible Kapton® handle.

The gas pressure can vary with the chamber used for sputtering. In one embodiment, the Ar sputtering gas pressure ranges from about 10⁻⁵ Torr to about 1 Torr, such as, for example, from about 0.1 mTorr to about 500 mTorr, from about 1 mTorr to about 50 mTorr, and from about 5 mTorr to about 10 mTorr.

In yet another embodiment, the thickness of the straining layer ranges from about 0.1 nm to about 10000 nm.

In yet another embodiment, the temperature and/or rate at which the straining layer deposition is performed is varied to induce different strains.

In another embodiment, a handle that was previously curved using another technique induces the strain. In this embodiment the handle could be curved by various techniques such as, but not limited to, a curvature induced during manufacturing or delivery (e.g. a rolled sheet of plastic that retains its shape), by curving the handle around a cylinder and heating to reshape the handle, by curving the handle around a cylinder and elastically deforming to promote curvature, by curving the handle and depositing a material on the surface to maintain the curvature, the use of a multilayer handle where the materials are bonded together while curved, the use of a multilayer handle where the handle is created at a different temperature than etching is performed at where upon temperature change a curvature is created.

In another embodiment, the difference in coefficient of thermal expansion (CTE) between the handle and the growth substrate could be used to create a strain in the handle by performing the lift-off etch at a different temperature than at which the handle and wafer were bonded together. In this embodiment one example is where the bonding of the handle is performed at a lower temperature than the epitaxial lift off etch is performed; in this case the handle will curve away from the wafer if the CTE of the handle is less than that of the wafer or will curve towards the wafer if the CTE of the handle is greater than that of the wafer. A second example of this is where the bonding of the wafer is done at a higher temperature than the epitaxial lift off etch is performed; in this case the handle will curve toward the wafer if the CTE of the handle is less than that of the wafer or will curve away from the wafer if the CTE of the handle is greater than that of the wafer.

A combination of compressive and tensile strains can be achieved by depositing multiple straining layers, as shown in FIGS. 2(c) and 2(d). For example, a combination of strains can be achieved using multi-layer metal stacks with controlled thickness and varying strain conditions. For instance, a tensile strained layer with compressive strained layer on top of it, or a compressive strained layer with tensile strained layer on top of it can be employed by controlling the metal deposition condition. By using a multi-layer metal stack, the bulk strain and the strain near surface can be controlled separately. Also, a straining layer can be sputtered on both sides of the flexible handle with various combinations and degrees of tensile and compressive strain.

In some embodiments, one or more straining layers are disposed on the growth substrate to control strain during ELO. One or more straining layers can be deposited directly on the growth substrate, between the growth substrate and an epilayer, and/or over an epilayer, i.e., further away from the growth substrate than the epilayer.

In some embodiments, one or more straining layers are deposited on the growth substrate and the handle.

An additional control of strain could be achieved by varying the handle layer thickness, that is, a thinner Kapton handle will curve more for a given strain condition in a deposited metal.

In another embodiment, the handle is made from a plastic material, a polymeric material or an oligomeric material. The handle may have a thickness ranging from about 10 μm to about 250 μm such as, for example, from about 15 μm to about 200 μm, and from about 25 μm to about 125 μm.

Suitable examples of materials comprising the handle include materials such as polyimide, e.g., Kapton®, polyethylene, polyethylene glycol (PEG), polyethylene terephthalate (PET), polyethylene terephthalate glycol (PET-g), polystyrene, polypropylene, polytetrafluoroethylene (PTFE), e.g. Teflon®, polyvinylidene difluoride and other various partially fluorinated polymers, nylon, polyvinyl chloride, chlorosulfonated polyethylene (CSPE),e.g., Hypalon®, and Poly(p-phenylene sulfide).

Suitable examples of materials comprising the handle also include metal foils such as stainless steel, copper, molybdenum, tantalum, nickel and nickel alloys, e.g., Hastelloy®, bronze, gold, noble metal coated foils, and polymer coated foils.

In some embodiments, the handle material is flexible, not confined, and is free to deform and bend during the ELO process.

The growth substrate may comprise any number of materials, including single crystal wafer materials. In some embodiments, the growth substrate may be chosen from materials that include, but are not limited to, Ge, Si, GaAs, InP, GaN, AlN, GaSb, InSb, InAs, SiC, CdTe, sapphire, and combinations thereof. In some embodiments, the growth substrate comprises GaAs. In some embodiments, the growth substrate comprises InP. In some embodiments, the materials comprising the growth substrate may be doped. Suitable dopants may include, but are not limited to, Zinc (Zn), Mg (and other group IIA compounds), Zn, Cd, Hg, C, Si, Ge, Sn, O, S, Se, Te, Fe, and Cr. For example, growth substrate may comprise InP doped with Zn and/or S.

In yet another embodiment, the handle having one or more straining layers disposed thereon can be bonded to a growth substrate. In certain embodiments, the handle is bonded using cold welding technology or for conventional ELO with an adhesive layer such as wax. A sample of the strained handle and growth substrate containing an active epilayer can then be etched in, for example, dilute HF (DHF).

In another embodiment, for further acceleration of ELO, DHF can be heated on a hot plate or the concentration of HF can be increased.

In yet another embodiment, the present disclosure provides a process of fabricating a thin film device for epitaxial lift off comprising depositing one or more straining layers on a handle, wherein the one or more straining layers induce tensile, compressive or near-neutral strain to accelerate curvature of the handle.

In some embodiments, the at least one strain on the handle induces a curvature of the handle. In some embodiments, the at least one strain on the handle induces a curvature of the handle toward a growth substrate. In some embodiments, the at least one strain on the handle induces a curvature of the handle away from a growth substrate. In some embodiments, the tensile strain upon deposition accelerates curvature of the handle inwards toward a growth substrate.

In one embodiment, the strain on the handle changes the flow of etchant to the sacrificial layer. In one embodiment, the strain on the handle improves the flow of etchant solution to the etch front by, for example, opening the etch front.

In some embodiments, the one or more straining layers induce strain in the sacrificial layer. The induced strain can be tensile, compressive, or near-neutral strain. In some embodiments, the strain in the sacrificial layer accelerates the etch rate of the sacrificial layer. In some embodiments, this acceleration is independent of any acceleration from improved transport of etchant to the etch front.

In one embodiment, the present disclosure provides a method of fabricating a thin film device for epitaxial lift off comprising, providing a growth substrate and a handle, depositing one or more straining layers on at least one of the growth substrate and the handle, and bonding the handle optionally having the one or more straining layers disposed thereon to the growth substrate. In some embodiments, one or more straining layers are deposited on the growth substrate and the handle. In some embodiments, the growth substrate has an epilayer disposed thereon. In some embodiments, the growth substrate has a sacrificial layer and an epilayer disposed thereon. In some embodiments, the epilayer is disposed on the sacrificial layer.

In yet another embodiment, the present disclosure provides a method for epitaxial lift off comprising, depositing an epitaxial layer over a sacrificial layer disposed on a growth substrate; depositing one or more straining layers on at least one of the growth substrate and a handle; bonding the handle to the wafer; and etching the sacrificial layer. In some embodiments, one or more straining layers are deposited on the growth substrate and the handle. In certain embodiments, the sacrificial layer can be etched with hydrogen fluoride.

In some embodiments, bonding the handle to the growth substrate is performed by a cold welding process.

Materials and layers may be deposited in accordance with techniques known in the art.

### EXAMPLES

The present disclosure will now be described in greater detail by the following non-limiting examples. It is understood that the skilled artisan will envision additional embodiments consistent with the disclosure provided herein.

### Example 1

In this example, the epitaxial layer structures were grown by gas-source molecular beam epitaxy (GSMBE) on Zn-doped (100) p-GaAs substrates. The growths started with a 0.2 μm thick GaAs buffer layer. Then, 0.1 μm lattice matched In_{0.49}Ga_{0.51}P etching stop layer was grown, followed by 0.1 μm thick GaAs protection layer. Subsequently, a 0.01 μm thick AlAs sacrificial layer was grown. Then, an inverted GaAs solar cell active region was grown as follows: 0.2 μm thick, 5×10¹⁸ cm⁻³ Si-doped GaAs contact layer, 0.025 μm thick, 2×10¹⁸ cm³ Si-doped In_{0.49}Ga_{0.51}P window layer, 0.15 μm thick, 1×10¹⁸ cm⁻³ Si-doped n-GaAs emitter layer, 3.5 μm thick, 2×10¹⁷ cm⁻³ Be-doped p-GaAs base layer, 0.075 μm thick, 4×10¹⁷ cm⁻³ Be-doped In_{0.49}Ga_{0.51}P back surface field (BSF) layer, and a 0.2 μm thick, 2×10¹⁸ cm⁻³ Be-doped p-GaAs contact layer.

After growth, an Ir(150 Å)/Au(8000 Å) contact layer was deposited onto a 50 μm-thick Kapton® sheet and a Au (600 Å) layer was deposited on the GaAs epitaxial layers by electron-beam evaporation. The substrate and plastic sheet were bonded via cold-welding and then immersed into a solution of HF:H₂O (1:10) to perform ELO. Immediately after the ELO process, the thin film was cleaned by plasma etching with BCl₃ and Ar gases. Then, it was cut into quarter-wafer pieces for solar cell fabrication.

Solar cell fabrication started with photolithography for grid patterning and by depositing Ni(50 nm)/Ge(320 nm)/Au(650 nm)/Ti(200 nm)/Au(9000 nm) by e-beam evaporation. The thin-film cell was annealed on a hot plate for 1 hr at 240° C. to form Ohmic contacts. Subsequently, mesas were defined by chemical etching, and the exposed highly-doped GaAs layer was removed. Finally, a ZnS(43 nm)/MgF₂(102 nm) bi-layer antireflection coating was deposited by e-beam evaporation to produce solar cells.

The current density-voltage (J-V) characteristics of the ELO processed GaAs photovoltaic cell measured under simulated AM1.5G illumination at 100 mW/cm² intensity was measured. The short circuit current density was 23.1 mA/cm², and the open circuit voltage was 0.92 V, the fill factor was 75.6%, resulting in a power conversion efficiency of 16.1%. The external quantum efficiency peaked at 85%.

As described above, a bilayer protection scheme was employed comprising an etch stop layer (0.1 μm thick InGaP) and a protection layer (0.1 μm thick GaAs) to protect the parent GaAs wafer surface during the ELO process. The GaAs protection layer surface was decomposed by heat treating with a RTA tool. After the thermal treatment of the surface, the majority of large scale contamination was removed. After the RTA, the protection layer and etch-stop layer was removed by wet etching using H₃PO₄:H₂O₂:H₂O (3:1:25) and H₃PO₄:HCl (1:1), respectively. Surface roughness after protection removal (root mean square (RMS) roughness of 0.71 nm) was comparable with that of a fresh wafer (RMS roughness of 0.62 nm)

To compare the growth quality of the original and subsequent epitaxial layers, epitaxial lift off process was simulated by exposing the wafer with protection layer to a dilute solution of 7.5% HF:H₂O for 48 hr. After RTA treatment and epitaxial protection-layer removal, the substrate was loaded back into the GSMBE chamber and degassed. A layer structure was then grown on the original parent substrate with the same structures as that of the reference structure. GaAs solar cells, Hall-effect, photoluminescence, scanning transmission electron microscopy (STEM) and reflection high energy electron diffraction (RHEED) measurements for GaAs epitaxial layer on both the original and reused wafers indicate the nearly identical electrical and optical quality of the epitaxial film.

The fresh growth and regrowth interface qualities were also investigated after an ELO simulation. The cross sectional STEM images confirmed the nearly perfect crystalline growth for both fresh and regrown epitaxial films. The RHEED pattern also indicated the identical surface quality for those wafers. Furthermore, the surface chemistry studied by energy dispersive spectrometry (EDS), and x-ray photoelectron spectrometry (XPS) did not show significant difference between original and reused wafers.

### Example 2

The epitaxial layers were grown on GaAs layers by gas source molecular beam epitaxy. An AlAs layer (10 nm) was grown as a sacrificial ELO layer between the wafer and the active epitaxial layers Immediately following the growth, Ir was sputtered onto a 50 μm-thick Kapton sheet. Next, 0.8 μm of Au was deposited by E-beam evaporation and 1500 Å of Au was deposited by E-beam evaporation on the GaAs epitaxial layers. To test the effects of handle strain, various thickness of Ir were sputtered under different Ar gas pressures. After metal deposition, the wafer was cold welded to the handle by placing the Au-side of the wafer down on the plastic sheet and cold-weld bonded by applying pressure. Then, the GaAs wafer bonded to the Kapton sheet was immersed into an etching solution of HF:H₂O (1:10) to around 50° C. to selectively etch the AlAs layer.

Both compressive and tensile stressed handles expedited the ELO process compared with flat handles. When a 10 nm-thick AlAs sacrificial layer was employed, and the flexible handle was fixed on the Teflon stage with Kapton tape, it took around ten days to prevent bending of the handle. However, with the ELO process and using a tensile strained handle, it took about 24 hrs. The fastest etch rate was achieved with compressive strain which took less than 8 hrs (FIG. 4).

What is claimed is:

1. A thin film device for epitaxial lift off comprising:
a handle and one or more straining layers disposed on the handle, wherein the one or more straining layers induce a curvature of the handle.

2. The device of claim 1, wherein the one or more straining layers induce a curvature of the handle toward a growth substrate.

3. The device of claim 1, wherein the one or more straining layers induce a curvature of the handle away from a growth substrate.

4. The device of claim 1, wherein the one or more straining layers are composed of at least one material chosen from a metal, a semiconductor, a dielectric and a non-metal.

5. The device of claim 1, wherein the one or more straining layers are composed of at least one metal chosen from Iridium, Gold, Nickel, Silver, Copper, Tungsten, Platinum, Palladium, Tantalum, Molybdenum, Chromium and alloys thereof.

6. A thin film device for epitaxial lift off comprising:
a growth substrate,
a handle,
and one or more straining layers disposed on at least one of the growth substrate and the handle,
wherein the handle optionally having the one or more straining layers disposed thereon is bonded to the growth substrate, and wherein the one or more straining layers induce at least one strain on the handle chosen from tensile strain, compressive strain and near-neutral strain.

7. The device of claim 6, wherein the at least one strain on the handle induces a curvature of the handle.

8. The device of claim 7, wherein the at least one strain on the handle induces a curvature of the handle toward the growth substrate.

9. The device of claim 7, wherein the at least one strain on the handle induces a curvature of the handle away from the growth substrate.

10. The device of claim 6, wherein the one or more straining layers are disposed on the growth substrate and the handle.

11. The device of claim 6, further comprising an epilayer disposed on the growth substrate, wherein the one or more straining layers induce at least one strain on at least one of the handle and the epilayer.

12. The device of claim 6, further comprising a sacrificial layer and an epilayer disposed on the growth substrate, wherein the one or more straining layers induce at least one strain on at least one of the sacrificial layer, the epilayer, and the handle.

13. The device of claim 6, wherein the one or more straining layers are composed of at least one metal chosen from Iridium, Gold, Nickel, Silver, Copper, Tungsten, Platinum, Palladium, Tantalum, Molybdenum, Chromium and alloys thereof.

14. The device of claim 6, wherein the thin film device is a solar cell device.

15. A thin film device for epitaxial lift off comprising:
at least one sacrificial layer; and
at least one straining layer disposed on a handle,
wherein the at least one straining layer is composed of at least one material chosen from a metal, semiconductor, dielectric and non-metal, and
wherein the at least one straining layer induces a curvature of the handle.

16. The device of claim 15, wherein the at least one sacrificial layer comprises aluminum arsenide, alloys thereof, or combinations thereof.

17. The device of claim 15, wherein the at least one straining layer is composed of at least one metal chosen from Iridium, Gold, Nickel, Silver, Copper, Tungsten, Platinum, Palladium, Tantalum, Molybdenum, Chromium, and alloys thereof.

18. The device of claim 15, wherein the at least one sacrificial layer has a thickness ranging from about 1 nm to about 200 nm.

19. The device of claim 15, wherein the at least one straining layer has a thickness ranging from about 0.1 nm to about 10000 nm.

20. The device of claim 15, wherein the thin film device is a solar cell device.
